(19) United States
(12) Patent Application Publication
(10) Pub. No.: US 2017/0276929 A1
(43) Pub. Date: Sep. 28, 2017

(54) Pop-Up Laminate Structure Including Miniature Optical Components

(71) Applicant: President and Fellows of Harvard College, Cambridge, MA (US)

(72) Inventors: Zhi Ern TEOH, Cambridge, MA (US); Michael KARPELSON, Newton, MA (US); Robert J. WOOD, Cambridge, MA (US)

(73) Assignee: President and Fellows of Harvard College, Cambridge, MA (US)

(21) Appl. No.: 15/511,040

(22) PCT Filed: Sep. 16, 2015
(86) PCT No.: PCT/US2015/050366

§ 371 Date: Mar. 14, 2017

Related U.S. Application Data
(60) Provisional application No. 62/050,829, filed on Sep. 16, 2014.

(51) Int. Cl. G02B 26/08; H02K 33/16; B81C 1/00; B81B 3/00; H01L 41/09

(52) U.S. Cl. CPC G02B 26/085; G02B 26/0858; B81B 3/0051; H01L 41/0933; B81C 1/00007; H02K 33/16; B81B 2201/047; B81B 2201/032

(57) ABSTRACT

A pop-up laminate structure includes rigid layers, at least one flexible layer, at least one optical component, and an actuator. At least one of the rigid layers defines gaps extending there through to form a plurality of rigid segments separated by the gaps in the rigid layer. The flexible layer is bonded to the rigid segments to form joints for folding. The optical component is mounted to a rigid layer and configured to generate, capture or alter a light beam. The actuator is mounted to at least one of the rigid layers and configured to displace at least one rigid segment that, in turn, displaces the optical component. At least some of the layers are bonded to adjacent layers only at selected locations forming islands of inter-layer bonds to allow expansion of the laminate into an expanded three-dimensional structure.

### GOVERNMENT SUPPORT

The invention was supported, in whole or in part, by grants under Contract Number W911NF-08-2-0004 from the Army Research Laboratory and Contract Number CCF-0926148 from the National Science Foundation. The U.S. Government has certain rights in the invention.

### BACKGROUND

Pop-up micro electro mechanical systems (MEMS) are fabricated by a process capable of creating complex millimeter-scale electromechanical devices, as described in U.S. patent application Ser. No. 13/961,510, filed on 7 Aug. 2013 and in U.S. Patent App. No. 61/862,066, filed on 4 Aug. 2013, both of which are incorporated herein by reference in their entirety.

### SUMMARY

A pop-up laminate structure, including an optical device, can comprise a plurality of rigid layers, wherein at least one of the rigid layers defines gaps extending through the rigid layer to form a plurality of rigid segments separated by the gaps in the rigid layer; at least one flexible layer that is substantially less rigid than the rigid segments, wherein the flexible layer is bonded to the rigid segments such that the flexible layer is exposed at the gaps between the rigid segments to form joints for folding; at least one optical component mounted to a rigid layer and configured to generate, capture or alter a light beam; and an actuator mounted to a rigid layer and configured to displace at least one rigid segment that, in turn, displaces the optical component. At least some of the layers are bonded to adjacent layers only at selected locations forming islands of inter-layer bonds to allow expansion of the laminate into an expanded three-dimensional structure when the laminate is folded at the joints.

A method for fabricating a pop-up laminate structure including an optical device includes actuating an actuator mounted to at least one rigid segment among a plurality of rigid segments separated by gaps in a rigid layer. The rigid segments are flexibly joined by a flexible layer, and an optical device is mounted to at least one of the rigid segments. Actuation of the actuator displaces or changes the orientation of the optical device; and the optical device is used to generate, capture, or alter light using the optical device.

The pop-up MEMS paradigm can be used to manufacture complex articulated mechanisms with integrated pick-and-place components, such as electronics, actuators, and optics, making this process attractive for miniature optical devices. Here, examples of the following two such devices are presented: a one-degree-of-freedom (1-DOF) beam scanning mechanism and a three-degree-of-freedom (3-DOF) spherical parallel mechanism (SPM) capable of three-axis rotation of a beam-steering mirror, laser diode, or miniature camera. Various other devices can be made using the same principle.

Pop-up laminate structures with optical components and methods for fabricating and using such structures are described herein, where various embodiments of the apparatus and methods may include some or all of the elements, features and steps described below.

As described herein, embodiments of a pop-up laminate structure include at least the following components: a plurality of rigid layers, wherein at least one of the rigid layers defines gaps extending through the rigid layer to form a plurality of rigid segments separated by the gaps in the rigid layer; at least one flexible layer that is substantially less rigid than the rigid segments, wherein the flexible layer is bonded to the rigid segments such that the flexible layer is exposed at the gaps between the rigid segments to form joints for folding; at least one optical component mounted to a rigid layer and configured to generate, capture or alter a light beam; and an actuator mounted to a rigid layer and configured to displace at least one rigid segment that, in turn, displaces the optical component. At least some of the layers are bonded to adjacent layers only at selected locations forming islands of inter-layer bonds to allow expansion of the laminate into an expanded three-dimensional structure when the laminate is folded at the joints.

### BRIEF DESCRIPTION OF THE DRAWINGS

FIG. 1 shows a generalized process flow chart for fabricating a printed circuit MEMS.

FIGS. 2 and 3 show the pop-up assembly of an electromagnetic actuator 29, wherein the magnetic coil 31 and the permanent magnet 33 undergo vertical translation during pop-up assembly from a flat configuration, as shown in FIG. 2, to position the permanent magnet 33 inside the magnetic coil 31, as shown in FIG. 3.

FIG. 4 shows a three-degree-of-freedom spherical-mechanical assembly. As shown in (A), the spherical-parallel mechanism 26 is manufactured as a laminate. Using pins to separate the ground link 30 and the base link 46, as shown in (B), a vertical translation initiates a sequence that folds the spherical-parallel mechanism 26 into its three-dimensional state. When in its final configuration, as shown in (C), a laser is used to remove the assembly scaffold.

FIG. 5 is a magnified view of the assembly in the second-to-last stage of the pop-up process of FIG. 4, with reference labels for the cut sections 56 and mobile joints 54 that are locked at particular locations for removing structures and locking the position of links in the popped-up configuration.

FIG. 6 illustrates the spherical-parallel-mechanism (SPM) motion, wherein by actuating the actuated links 32, as shown in (A)-(C), the stage link 36 is orientated using three angular inputs at the spherical-parallel-mechanism's base. By coordinating the angular inputs, the stage can achieve a workspace parameterized by a pointing cone of around 140° and a torsion of ±30°. If all the actuated links 32 are rotated by an equal amount, as shown in (D), the stage undergoes a rotation that is concentric to the ground link 30.

FIG. 7 shows actuators 29 incorporated at the base of the ground link 30 and motion produced in the actuated links 32.

FIGS. 8-10 show three-degree-of-freedom spherical-parallel-mechanism assembly, wherein a vertical translation initiates a sequence that folds the spherical-parallel mechanism 26 into its three-dimensional state by using the pins to separate the ground link 30 and the base link 46.

FIGS. 11-14 show a sequence of stages in the pop-up expansion of a scaffold assembly on which an optical device can be mounted.

In the accompanying drawings, like reference characters refer to the same or similar parts throughout the different views; and apostrophes are used to differentiate multiple instances of the same or similar items sharing the same reference numeral. The drawings are not necessarily to scale; instead, emphasis is placed upon illustrating particular principles in the exemplifications discussed below.

### DETAILED DESCRIPTION

The foregoing and other features and advantages of various aspects of the invention(s) will be apparent from the following, more-particular description of various concepts and specific embodiments within the broader bounds of the invention(s). Various aspects of the subject matter introduced above and discussed in greater detail below may be implemented in any of numerous ways, as the subject matter is not limited to any particular manner of implementation. Examples of specific implementations and applications are provided primarily for illustrative purposes.

Unless otherwise herein defined, used or characterized, terms that are used herein (including technical and scientific terms) are to be interpreted as having a meaning that is consistent with their accepted meaning in the context of the relevant art and are not to be interpreted in an idealized or overly formal sense unless expressly so defined herein. For example, if a particular composition is referenced, the composition may be substantially, though not perfectly pure, as practical and imperfect realities may apply; e.g., the potential presence of at least trace impurities (e.g., at less than 1 or 2%) can be understood as being within the scope of the description; likewise, if a particular shape is referenced, the shape is intended to include imperfect variations from ideal shapes, e.g., due to manufacturing tolerances. Percentages or concentrations expressed herein can represent either by weight or by volume. Processes, procedures and phenomena described below can occur at ambient pressure (e.g., about 50-120 kPa—for example, about 90-110 kPa) and temperature (e.g., −20 to 50° C.—for example, about 10-35° C.) unless otherwise specified.

Although the terms, first, second, third, etc., may be used herein to describe various elements, these elements are not to be limited by these terms. These terms are simply used to distinguish one element from another. Thus, a first element, discussed below, could be termed a second element without departing from the teachings of the exemplary embodiments.

Spatially relative terms, such as “above,” “below,” “left,” “right,” “in front,” “behind,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly. p Further still, in this disclosure, when an element is referred to as being “on,” “connected to,” “coupled to,” “in contact with,” etc., another element, it may be directly on, connected to, coupled to, or in contact with the other element or intervening elements may be present unless otherwise specified.

The terminology used herein is for the purpose of describing particular embodiments and is not intended to be limiting of exemplary embodiments. As used herein, singular forms, such as “a” and “an,” are intended to include the plural forms as well, unless the context indicates otherwise. Additionally, the terms, “includes,” “including,” “comprises” and “comprising,” specify the presence of the stated elements or steps but do not preclude the presence or addition of one or more other elements or steps.

Additionally, the various components identified herein can be provided in an assembled and finished form; or some or all of the components can be packaged together and marketed as a kit with instructions (e.g., in written, video or audio form) for assembly and/or modification by a customer to produce a finished product.

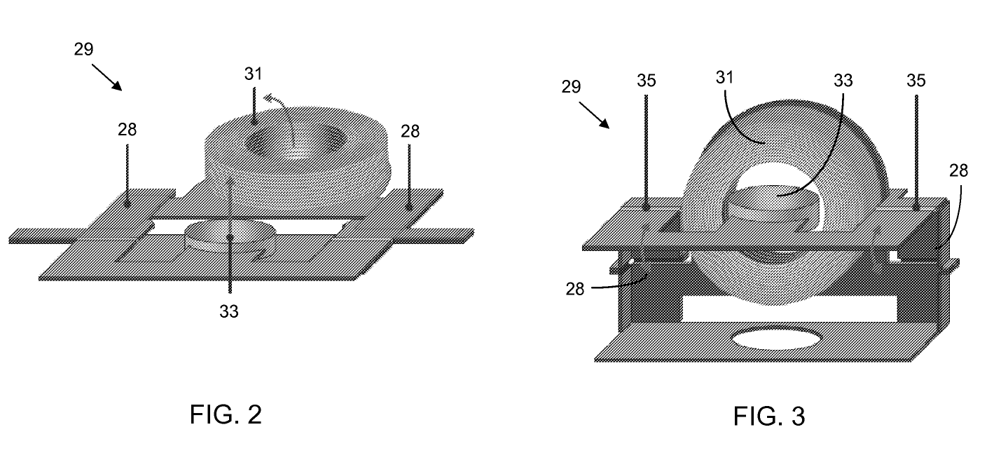

Beam-scanning mechanisms are found in a variety of optical devices, including laser barcode scanners, scanning laser rangefinders, and scientific instrumentation. To achieve the scanning functionality, such mechanisms can either move the source of the beam directly (e.g., where a laser diode is used) or move a mirror that redirects the beam to the desired location. The latter approach is employed here in a first embodiment to produce a pop-up device. In particular embodiments, a simple electromagnetic actuator 29 is realized by positioning a permanent magnet 33, constrained to pivot around its axis, inside a coil 31, as shown in FIGS. 2 and 3. By passing current in either direction through the coil 31, a magnetic field is created, acting essentially as an air-core electromagnet. The opposite poles of the electromagnet 31 and the permanent magnet 33 attract, producing a torque on the magnet 33. An arm may then be attached to the permanent magnet 33, allowing it to drive a useful load, such as a beam-steering mirror, laser diode, or miniature camera.

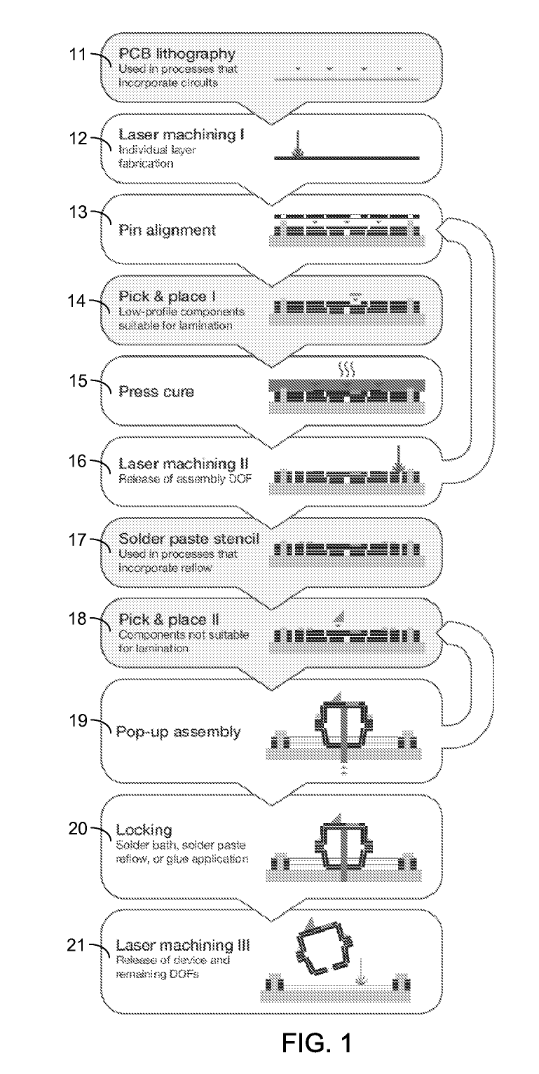

Further, the pop-up mechanism can be used to implement the rotary actuator 29. As shown by the process flow in FIG. 1, PCB lithography can be first used (in step 11) to form conductive circuits on a surface of the layered structure. Individual layers in the laminate can be structured via a laser machining step 12; and the layers can be aligned using pins that pass through orifices in the layers in step 13. A pick-and-place step 14 can be used to mount low-profile components into the layered structure before lamination. The layered structure can then be press cured in step 15 to form the laminate. Laser machining can then be used in step 16 to release assembly degrees of freedom for pop-up expansion of the laminate structure. Steps 13-16 can be iteratively repeated multiple times to form more elaborate laminate structures. In step 17, solder paste stencil deposition can be used in processes that incorporate reflow.

Here, the permanent magnet 33 and magnetic coil 31 can be prefabricated components positioned on the pop-up MEMS laminate via pick and place—physical placement (shown as the Pick and Place II process step 18 in FIG. 1). Once the magnet 33 and coil 31 are secured to the flat pop-up MEMS laminate, the laminate unfolds (via pop-up assembly 19) into a three-dimensional mechanism that positions the magnet 33 inside the coil 31 and allows the magnet 33 to pivot along its axis. Additional components can also be mounted to the laminate structure (step 18) after the pop-up assembly/unfolding step(s) 19.

The unfolding process 19 of fabrication is constrained by two Sarrus linkages 28 and 41 that constrain the magnet 33 to rise vertically and constrain the coil 31 to rise and rotate by 90 degrees. After the unfolding process is complete, the unfolding mechanism is locked in place using solder or glue (shown as the locking process step 20 in FIG. 1); and the flexures that allow the magnet 33 to pivot inside the coil 31 are released by laser machining (shown as the laser machining III process step 21 in FIG. 1). The layered nature of pop-up MEMS designs allows a copper-laminated polymer layer to be introduced into the laminate. After patterning, this layer can act as a printed circuit board to house drive and control electronics associated with the actuator 29. The board may be populated at the same time that other pick and place components, such as the magnet 33, coil 31, and mirror, are delivered.

In various embodiments of the method, any or all of steps 11, 14, 17, and 18 may be omitted. Further discussion of aspects of this methodology and pop-up laminate structures produced therefrom can be found in U.S. Pat. No. 8,834,666.

Note that pop-up MEMS can produce very complex and diverse folding mechanisms; therefore, the simple rotary actuator 29 can be implemented in a number of different ways. In the illustrated embodiment of FIGS. 2 and 3, the magnetic coil 31 and the permanent magnet 33 rise during unfolding; and the coil 31 slides over the magnet 33. Other embodiments may comprise any of the following: a stationary coil 31 with the folding mechanism positioning the magnet 33 inside the coil 31; a stationary magnet 33 with the folding mechanism positioning the coil 31 around the magnet 33; or other folding mechanisms where both the coil 31 and magnet 33 are moved into the desired position using appropriate mechanical linkages.

In this embodiment, the folding is achieved using Sarrus linkages 28 and 41 in the form of laminated components that enable vertical and rotating motion during pop-up assembly. The magnetic coil 31, which is applied as a pick-and-place component, undergoes 90° rotation during pop-up assembly. The magnet 33, meanwhile, which also is applied to the structure via a pick-and-place procedure, undergoes a vertical transition (in the orientation shown) during pop-up assembly. Once assembled, the principle flexures 35 (where the flexible layer is exposed by gaps between the rigid segments) enable actuated rotary motion when electric current flows through the magnetic coil 31 to generate a magnetic field that displaces the magnet 33. The dimensions (height, width and depth) of this actuator 29 can each be about 10 mm or less (e.g., 5-10 mm).

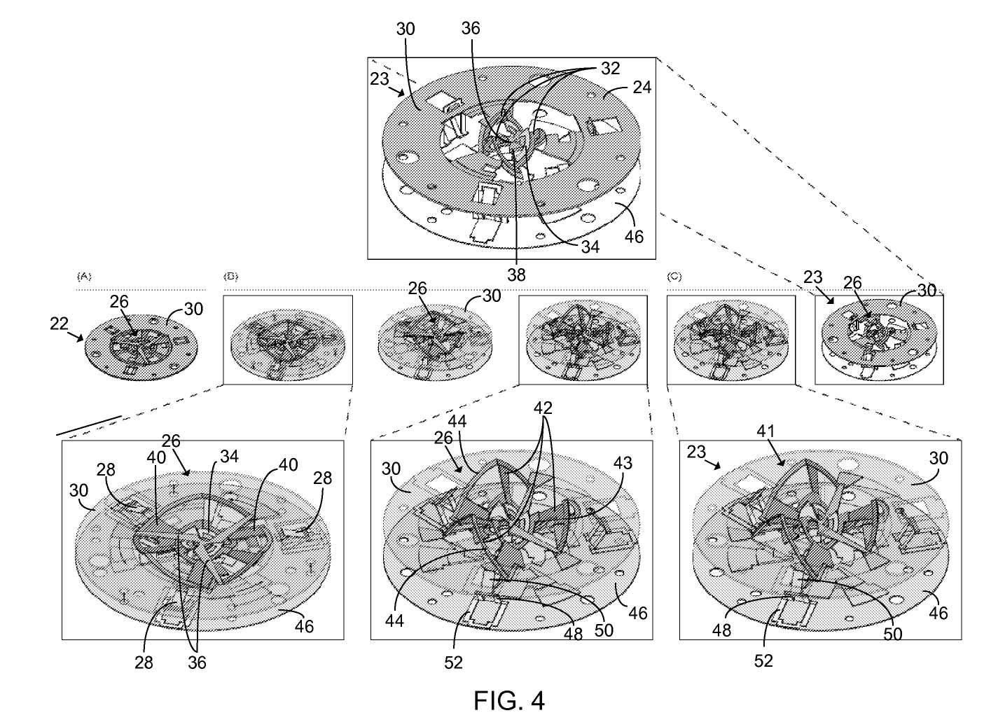

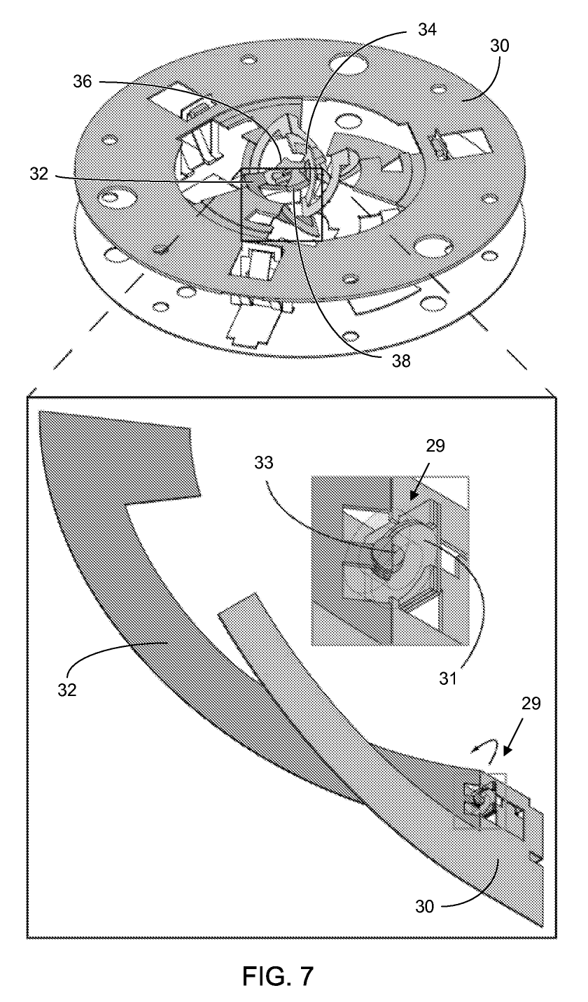

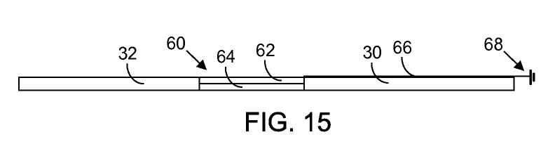

Further, pop-up MEMS can be used to manufacture much more complex optical mechanisms, such as the three-degree-of-freedom spherical-parallel mechanisms (SPM) 26 shown in FIGS. 4-14, which can be actuated by coupling links 30 and 32 to the above-described rotary actuator 29, as shown in the magnified inset of FIG. 7, so that the relative displacement of the magnetic coil 31 and permanent magnet 33 that occurs upon actuation produces a resulting relative pivoting of the links 30 and 32 at the hinge where the rotary actuator 29 is mounted. The spherical-parallel mechanisms 26 can accordingly be used to control and manipulate the orientation (along three rotational axes) of an optical component 58, such as a mirror, laser diode, or miniature camera, mounted to the spherical-parallel mechanism 26. The spherical-parallel mechanism 26 is based on Gosselin and Hammel's design. This design is adapted to allow planar fabrication in a layered process, such as pop-up MEMS; and a specialized pop-up mechanism is designed to assemble the three-dimensional structure of the spherical-parallel mechanism 26 from the flat laminate 22.

The pop-up assembly step can use a single linear degree of freedom to cause a structure to transform from its two-dimensional (collapsed) state 22 into its three-dimensional (expanded) state 23.

As shown in FIG. 4, a three-degree-of-freedom spherical-parallel mechanism 26 is manufactured as a flat laminate 22 that includes two parts, the assembly scaffold 24 and the spherical-parallel mechanism 26. The spherical-parallel mechanism 26 includes an actuated link 32 pivotably mounted to the ground link 30, an intermediary link 34 pivotably mounted to the actuated link 32, and an inner stage link 36 pivotably mounted to the intermediary link 34 and including an orientation mark 38. In this embodiment, the assembly scaffold 24 incorporates three vertical-displacement Sarrus linkages 28 (comprising vertical displacement Sarrus links 48 and 50 pivotably mounted to stop links 52) that constrain the ground link 30 to move vertically with respect to the base link 46. Using this vertical motion, a set of three angular displacement Sarrus linkages 41 (comprising angular displacement Sarrus links 43 and 44) engages a set of three fold guides (comprising sections fold guide links 40 and 42). Fold guide link 40 determines the angular displacement of the ground link 30, while fold guide link 42 determines the angular displacement of the stage link 36. The combined action of fold guide link 40 and fold guide link 42 sets the angular displacement between the two parts of the actuated link 32.

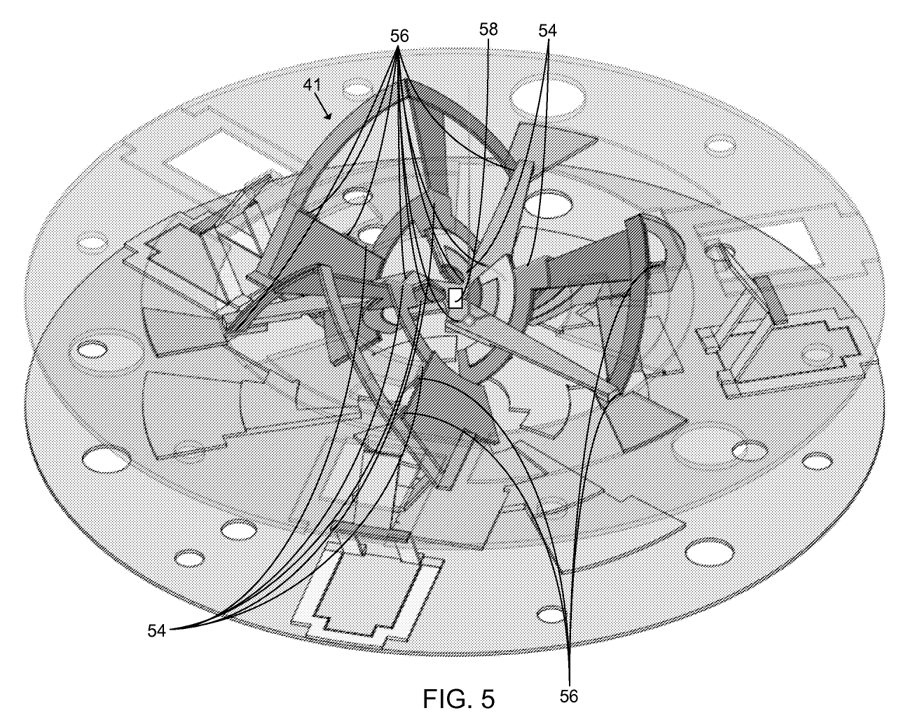

As shown in step (A) of FIG. 4, the spherical-parallel mechanism 26 is manufactured as a laminate. Using pins to separate the ground link 30 and the base link 46, as shown in (B), a vertical translation initiates a sequence that folds the spherical-parallel mechanism 26 into its three-dimensional state. When in its final expanded configuration 23 (once the desired vertical displacement of the ground link 30 is reached), as shown in (C), which also is reproduced in FIG. 5, a laser is used to remove the assembly scaffold at cut sections 56 (as shown in the laser machining III process step 21 of FIG. 1). Meanwhile, certain mobile joints 54 of the actuated links 32 are selectively locked (per the Locking process step shown in FIG. 1) using glue or other adhesive; if metallic pads are incorporated into the laminate, locking can be achieved via dip soldering. The locking completes the assembly of the spherical-parallel mechanism 26, while the laser cut releases the spherical-parallel mechanism 26 from the assembly scaffold 24.

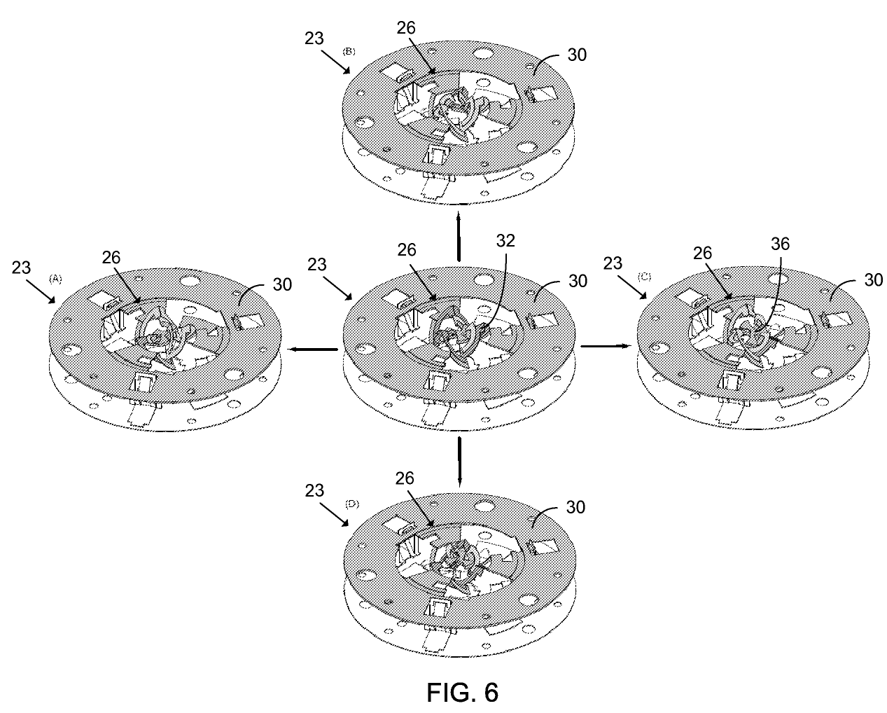

The spherical-parallel-mechanism (SPM) motion is shown in FIG. 6, wherein by actuating the actuated links 32, as shown in (A)-(C), the stage link 36 is orientated using three angular inputs at the spherical-parallel-mechanism's base link 46. By coordinating the angular inputs, the stage can achieve a workspace parameterized by a pointing cone of around 140° and a torsion of ±30°. If all the actuated links 32 are rotated by an equal amount, as shown in (D), the stage undergoes a rotation that is concentric to the ground link 30. The spherical-parallel mechanism 26 is shown in a neutral configuration at center.

FIG. 7 shows actuators 29 (one of which is shown in the magnified inset) incorporated at the base of the ground link 30 and the actuated link 32 and motion produced in the actuated links 32.

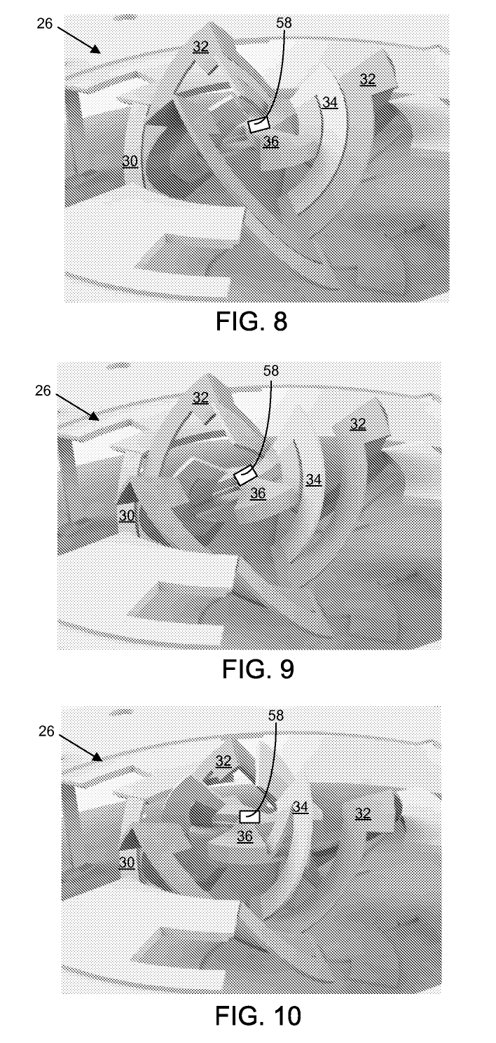

A three-degree-of-freedom spherical-parallel-mechanism assembly 26 is shown in FIGS. 8-10, wherein a vertical translation initiates a sequence that folds the spherical-parallel mechanism 26 into its three-dimensional state by using pins to separate the ground link 30 and the base link 46.

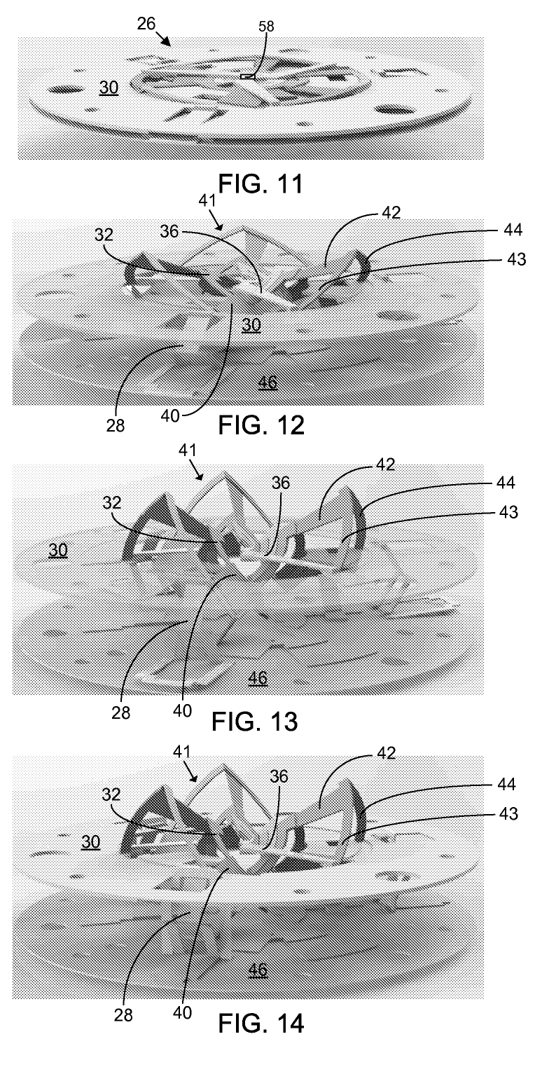

A sequence of stages in the pop-up expansion of a scaffold assembly on which an optical device can be mounted is shown in FIGS. 11-14. This actuation can be achieved by separating the base link 46 and the ground link 30 (to increase the gap therebetween).

After the spherical-parallel mechanism 26 is released from the assembly scaffold 24, rotational motion is imparted to three of the actuated links 32 to achieve the three-degree-of-freedom motion of the stage link 36, which can house a mirror, laser diode, camera, or other optical component 58. This motion can be generated by incorporating a simple electromagnetic actuator 29, similar to the one used in the one-degree-of-freedom beam scanning mechanism, into the connection between the ground link 30 and the actuated link 32. Other actuation methods, such as using a piezoelectric bimorph actuator 60 in the form of a laminate comprising a piezoelectric layer 62 and a second layer 64 formed, e.g., of metal and coupled via a conductive pathway 66 with a voltage source 68, as shown in FIG. 15, or using a transmission mechanism (e.g., a slider crank) can also be used. In additional embodiments, conductive traces may be incorporated into the flexible layers of the laminate to enable power and/or data connections to the optical component 58 and the actuators 29.

In describing embodiments of the invention, specific terminology is used for the sake of clarity. For the purpose of description, specific terms are intended to at least include technical and functional equivalents that operate in a similar manner to accomplish a similar result. Additionally, in some instances where a particular embodiment of the invention includes a plurality of system elements or method steps, those elements or steps may be replaced with a single element or step; likewise, a single element or step may be replaced with a plurality of elements or steps that serve the same purpose. Further, where parameters for various properties or other values are specified herein for embodiments of the invention, those parameters or values can be adjusted up or down by 1/100^{th}, 1/50^{th}, 1/20^{th}, 1/10^{th}, 1/5^{th}, 1/3^{rd}, 1/2, 2/3^{rd}, 3/4^{th}, 4/5^{th}, 9/10^{th}, 19/20^{th}, 49/50^{th}, 99/100^{th}, etc. (or up by a factor of 1, 2, 3, 4, 5, 6, 8, 10, 20, 50, 100, etc.), or by rounded-off approximations thereof, unless otherwise specified. Moreover, while this invention has been shown and described with references to particular embodiments thereof, those skilled in the art will understand that various substitutions and alterations in form and details may be made therein without departing from the scope of the invention. Further still, other aspects, functions and advantages are also within the scope of the invention; and all embodiments of the invention need not necessarily achieve all of the advantages or possess all of the characteristics described above. Additionally, steps, elements and features discussed herein in connection with one embodiment can likewise be used in conjunction with other embodiments. The contents of references, including reference texts, journal articles, patents, patent applications, etc., cited throughout the text are hereby incorporated by reference in their entirety; and appropriate components, steps, and characterizations from these references may or may not be included in embodiments of this invention. Still further, the components and steps identified in the Background section are integral to this disclosure and can be used in conjunction with or substituted for components and steps described elsewhere in the disclosure within the scope of the invention. In method claims, where stages are recited in a particular order—with or without sequenced prefacing characters added for ease of reference—the stages are not to be interpreted as being temporally limited to the order in which they are recited unless otherwise specified or implied by the terms and phrasing.

What is claimed is:

1. A pop-up laminate structure, including an optical device, comprising:
a plurality of rigid layers, wherein at least one of the rigid layers defines gaps extending through the rigid layer to form a plurality of rigid segments separated by the gaps in the rigid layer;
at least one flexible layer that is substantially less rigid than the rigid segments, wherein the flexible layer is bonded to the rigid segments such that the flexible layer is exposed at the gaps between the rigid segments to form joints for folding;
at least one optical component mounted to at least one of the rigid layers and configured to generate, capture or alter a light beam; and
an actuator mounted to a rigid layer and configured to displace at least one rigid segment that, in turn, displaces the optical component, wherein at least some of the layers are bonded to adjacent layers only at selected locations forming islands of inter-layer bonds to allow expansion of the laminate into an expanded three-dimensional structure when the laminate is folded at the joints.

2. The pop-up laminate structure of claim 1, wherein the optical component is selected from a mirror, a lens, a light source, and a light detector.

3. The pop-up laminate structure of claim 1, wherein the actuator is an electromagnetic actuator.

4. The pop-up laminate structure of claim 3, wherein the electromagnetic actuator includes:
a magnetic coil mounted to a first of the rigid segments; and
a permanent magnet mounted to a second of the rigid segments, wherein the rigid segments are configured to displaceably position the permanent magnet inside the magnetic coil.

5. The pop-up laminate structure of claim 4, wherein an arm is coupled with at least one of the magnetic coil and the permanent magnet so as to be displaced therewith, and wherein the arm is also coupled with the optical component to displace the optical component.

6. The pop-up laminate structure of claim 5, wherein the arm is one of the rigid segments.

7. The pop-up laminate structure of claim 5, wherein the rigid segments and the flexible layer are configured to form a Sarrus linkage.

8. The pop-up laminate structure of claim 1, wherein a plurality of actuators are included in the structure, and wherein each actuator is coupled with an arm that is also coupled with the optical component to displace the optical component with a plurality of degrees of freedom.

9. The pop-up laminate structure of claim 1, wherein the actuator is a piezoelectric bimorph actuator.

10. The pop-up laminate structure of claim 1, further comprising circuitry electrically coupled with the optical component.

11. A method for fabrication of a pop-up laminate structure including an optical device, the method comprising:
actuating an actuator mounted to at least one rigid segment among a plurality of rigid segments separated by gaps in a rigid layer, wherein the rigid segments are flexibly joined by a flexible layer, and wherein an optical device is mounted to at least one of the rigid segments;
with the actuation of the actuator, displacing or changing the orientation of the optical device; and
generating, capturing, or altering light using the optical device.

12. The method of claim 11, wherein the optical component is selected from a mirror, a lens, a light source, and a light detector.

13. The method of claim 11, wherein the actuator includes:
a magnetic coil mounted to a first of the rigid segments; and
a permanent magnet mounted to a second of the rigid segments, the method further comprising displacing the rigid segments to position the permanent magnet inside the magnetic coil.

14. The method of claim 13, wherein an arm is coupled with the optical component and with at least one of the magnetic coil and the permanent magnet, wherein the arm is displaced with displacement of the magnetic coil or the permanent magnet, and wherein that displacement of the arm also displaces the optical component.
